(19) United States
(12) Patent Application Publication
(10) Pub. No.: US 2024/0275340 A1
(43) Pub. Date: Aug. 15, 2024

(54) REACTIVELY MATCHED AND DISTRIBUTED POWER AMPLIFIER TOPLOGY

(71) Applicant: BAE Systems Information and Electronic Systems Integration Inc., Nashua, NH (US)

(72) Inventors: Michael Litchfield, Merrimack, NH (US); Bernard J. Schmanski, Merrimack, NH (US); Qin Shen-Schultz, Guilford, CT (US)

(73) Assignee: BAE Systems Information and Electronic Systems Integration Inc., Nashua, NH (US)

(21) Appl. No.: 18/168,805

(22) Filed: Feb. 14, 2023

(51) Int. Cl. H03F 3/24; H03F 1/56; H03F 3/195

(52) U.S. Cl. CPC H03F 3/245; H03F 1/56; H03F 3/195; H03F 2200/387; H03F 2200/451

(57) ABSTRACT

A power amplifier has multiple stages, wherein one stage includes nonuniform distributed power amplifier circuitry and an electrically subsequent stage includes reactively match power amplifier circuitry. There is a non 50 Ohm intermediate impedance between the distributed and reactively matched stages. The ratio of periphery between the subsequent reactively matched stage and the prior distributed stage being less than or equal to 2:1.

### TECHNICAL FIELD

The present disclosure relates generally to power amplifiers. More particularly, the present disclosure relates to power amplifier topology.

### BACKGROUND ART

Power amplifier monolithic microwave integrated circuits (MMICs) are an important component for many electronic systems, such as Synthetic Aperture Radar (SAR), electronic warfare, and security communications, amongst other electronic systems. In a power amplifier, the tradeoff between output power, efficiency, and bandwidth is a challenge in achieving the best performance possible. Today, there are at least two types of power amplifier topologies, namely, reactively matched power amplifiers (RMPA) and nonuniform distributed power amplifiers (NDPA).

Reactively matched power amplifiers have good output power and efficiency, but suffer from limited bandwidth. Distributed power amplifiers have good output power and bandwidth, but suffer from low efficiency.

One previous power amplifier is a Semi-Reactively Matched Amplifier (SRMA) having NDPA driver stage with input in center and two outputs on drain line driving reactively matched output stage. This power amplifier a 30 Ohm intermediate impedance, a 1.44:1 stage ratio, and is biased at 30 V, 100 mA/mm.

Another previous power amplifier was similar to this, but increased all FET sizes (same stage ratio), and added third stage due to low gain from increasing finger lengths for higher output power. This amplifier is biased at 30 V, 150 mA/mm.

Another previous power amplifier provides for the use of one distributed power amplifier stage to drive two reactively matched power amplifier stages. In this power amplifier, the stage ratios are all 2:1, not less. It utilizes a 50 Ohm intermediate impedance, however, it does not teach the usage of a non-50 Ohm intermediate impedance.

### SUMMARY OF THE INVENTION

Often, the desired bandwidth for a power amplifier is between these two power amplifier topologies (i.e., between the bandwidth provided by a reactively matched power amplifier and the bandwidth provide by a nonuniform distributed power amplifier). Thus, the present disclosure provides a solution for using the combination of the two power amplifier topologies (i.e., a combined reactively matched power amplifier and nonuniform distributed power amplifier) that allows the power amplifier of the present disclosure to achieve an optimal or sufficient output power, with a bandwidth and efficiency that is in between the extremes of the two topologies used individually (without mixing). For example, neither a nonuniform distributed power amplifier nor a reactively matched power amplifier is optimal for a 30-40 GHz bandwidth, but the combination of the two power amplifier topologies (i.e., a combined reactively matched power amplifier and nonuniform distributed power amplifier) is advantageous.

In one exemplary embodiment, there are two aspects of the power amplifier topology of the present disclosure that provide improved performance. Namely, (i) using a non-50 Ohm intermediate impedance between a nonuniform distributed amplifier stage and a reactively matched amplifier stage, and (ii) maintaining a ratio of periphery between the adjacent nonuniform distributed amplifier stage and subsequent reactively matched stage, wherein the ratio of periphery of the subsequent reactively matched stage relative to the adjacent nonuniform distributed amplifier stage is less than or equal to 2:1. The non-50 Ohm intermediate impedance may be in a range from 1 Ohm to 40 Ohm, such as 28 Ohm or 30 Ohm. Additionally, non-50 Ohm intermediate impedance may be in a range from 60 Ohm to 100 Ohm, such as 75 Ohm.

Another exemplary embodiment of the present disclosure provides a 3-stage balanced Reactively Matched Power Amplifier (RMPA)/nonuniform distributed power amplifier (NDPA) in a bandwidth of 28-40 GHz with 20 dB of small-signal gain, and 80 W of DC power consumption. This exemplary embodiment or other exemplary embodiments utilize or include, amongst other features, a GaN 0.18 um NFP 2 mil On-axis N+ process; a 3 Stage design, wherein the first stage includes 4 cells 4×75 um NDPA, and a second stage reactive match and a third stage reactive match; and a 1.5:2:4 drive ratio, wherein there is a half PA periphery in each stage, such that there are 4 unit cells 16×50 um used in output stage, 2 unit cell 16×50 um used in second stage, and NDPA 4×4×75 um used in first stage.

In another aspect, an exemplary embodiment of the present disclosure may provide a reactively matched distributed amplifier circuit topology that combines both reactively matched and distributed amplifier stages in order to achieve an efficiency and bandwidth that is in between those achieved by the two topologies by themselves. The first number of amplifier stages should be distributed, while the subsequent or last amplifier stages should be reactively matched. Any number of stages of each topology may be used. At the interface between the two stages, where the last distributed stage and first reactively matched stage meet, there may be a real, non-50 Ohm impedance that has been selected for matching. Also at this interface, the stage ratio of periphery from the reactively matched stage to the distributed stage should be less than 2:1 for optimal performance and to avoid early compression issues at high temperatures. This topology may also be balanced, by using a Lange coupler or any other 90 degree hybrid coupler at the input and output. The hybrid coupler may also be inserted at the interface between the last distributed stage and first reactively matched stage as well, since the early distributed stages will have a good input return loss.

In one aspect, an exemplary embodiment of the present disclosure may provide a power amplifier comprising: a first stage comprising a distributed power amplifier circuitry; a second stage that is electrically operative after the first stage, the second stage comprising a reactively matched power amplifier circuitry; and an intermediate impedance interface between the first stage and the second stage, wherein the intermediate impedance interface is a non-50 Ohm intermediate impedance; and a periphery ratio of the second stage to the first stage that is less than or equal to 2:1. This exemplary embodiment or another exemplary embodiment may further provide that the first stage comprises at least four unit cells in the distributed power amplifier circuitry. This exemplary embodiment or another exemplary embodiment may further provide that the second stage comprises at least two unit cells in the reactively matched power amplifier circuitry. This exemplary embodiment or another exemplary embodiment may further provide a third stage that is electrically operative after the second stage, the third stage comprising a reactively matched power amplifier circuitry. This exemplary embodiment or another exemplary embodiment may further provide that the periphery ratio of the first stage to the second stage to the third stage increases from the first stage to the second stage to the third stage. This exemplary embodiment or another exemplary embodiment may further provide that the periphery ratio of the first stage to the second stage to the third stage is 1.5:2:4. This exemplary embodiment or another exemplary embodiment may further provide that the third stage comprises at least four unit cells in the reactively matched power amplifier circuitry of the third stage. This exemplary embodiment or another exemplary embodiment may further provide an operative bandwidth that ranges from 28-40 Ghz. This exemplary embodiment or another exemplary embodiment may further provide an input comprising a first hybrid coupler, wherein the input is electrically operative before the first stage; and an output comprising a second hybrid coupler, wherein the output is electrically operative after the second stage.

In yet another aspect, another exemplary embodiment of the present disclosure may provide a method for a power amplifier, the method comprising: transmitting a signal to be amplified to a first stage of a power amplifier, wherein the first stage includes distributed power amplifier circuitry; amplifying the signal in the first stage; transmitting the signal to a second stage through an intermediate impedance interface between the first stage and the second stage, wherein the second stage includes reactively matched power amplifier circuitry; amplifying the signal in the second stage; and maintaining a periphery ratio of the second stage to the first stage to be less than or equal to 2:1. This exemplary embodiment or another exemplary embodiment may further include transmitting the signal a third stage that is electrically operative after the second stage, wherein the third stage includes reactively matched power amplifier circuitry; and amplifying the signal in the third stage. This exemplary embodiment or another exemplary embodiment may further provide that the periphery ratio of the first stage to the second stage to the third stage increases from the first stage to the second stage to the third stage. The periphery ratio of the first stage to the second stage to the third stage is 1.5:2:4. This exemplary embodiment or another exemplary embodiment may further include maintaining the intermediate impedance interface at a non-50 Ohm intermediate impedance.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 (FIG. 1) is a schematic block diagram of a power amplifier according to a first embodiment of the present disclosure.

FIG. 2 (FIG. 2) is a diagrammatic view of the topology of the power amplifier of the first embodiment.

FIG. 3A (FIG. 3A) is a diagrammatic view of the topology of a hybrid coupler in the power amplifier of the first embodiment.

FIG. 3B (FIG. 3B) is a diagrammatic view of the topology of a first stage and a second stage that include distributed power amplifier circuitry in the power amplifier of the first embodiment.

FIG. 3C (FIG. 3C) is a diagrammatic view of the topology of a third stage that includes reactively matched power amplifier circuitry in the power amplifier of the first embodiment.

FIG. 4 (FIG. 4) is a table that depicts the effective thermal resistances for an exemplary power amplifier of the present disclosure.

FIG. 5 (FIG. 5) is a schematic block diagram of a power amplifier according to a second embodiment of the present disclosure.

FIG. 6 (FIG. 6) is a diagrammatic view of the topology of the power amplifier of the second embodiment.

FIG. 7A (FIG. 7A) is a diagrammatic view of the topology of a first stage that includes distributed power amplifier circuitry in the power amplifier of the second embodiment

FIG. 7B (FIG. 7B) is a diagrammatic view of the topology of a second stage that includes reactively matched power amplifier circuitry in the power amplifier of the second embodiment.

FIG. 7C (FIG. 7C) is a diagrammatic view of the topology of a third stage that includes reactively matched power amplifier circuitry in the power amplifier of the second embodiment.

Similar numbers refer to similar parts throughout the drawings.

### DETAILED DESCRIPTION

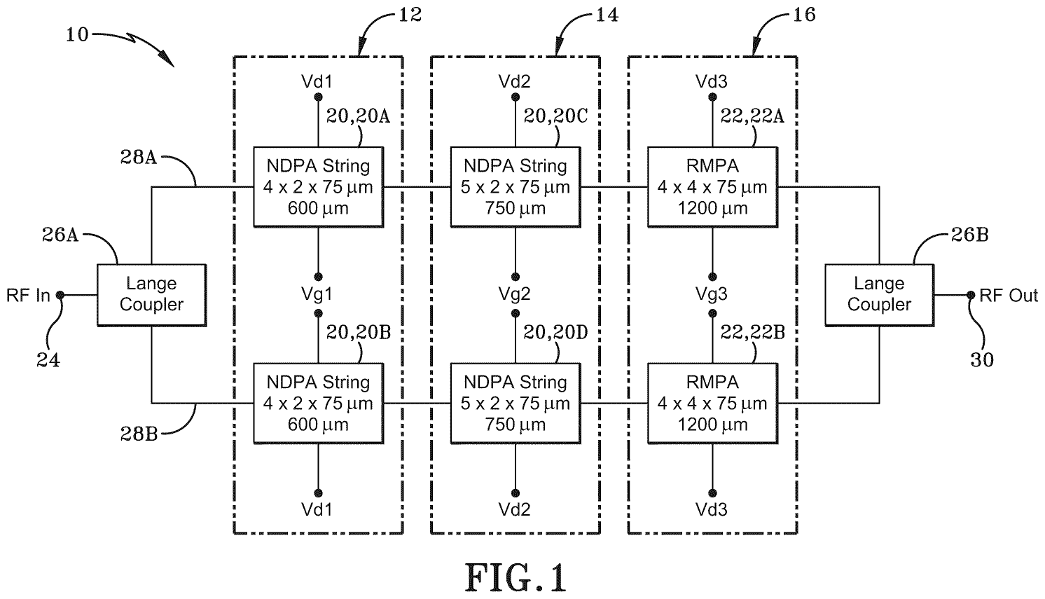

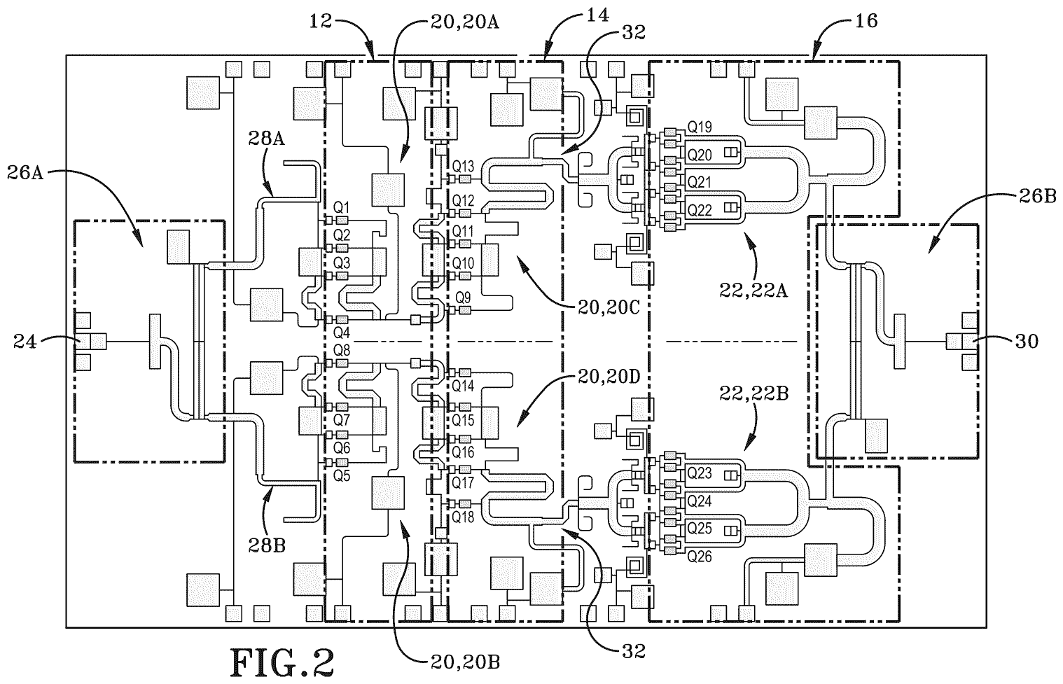

FIG. 1 schematically depicts the configuration of a power amplifier according to a first embodiment of the present disclosure generally at 10. FIG. 2 depicts an exemplary topology or configuration of the power amplifier 10.

Power amplifier 10 combines a nonuniform distributed power amplifier topology and a reactively matched power amplifier topology into a single power amplifier 10. Power amplifier 10 includes at least two stages, wherein at least one of the stages is a nonuniform distributed power amplifier stage and at least one of the other stages is a reactively matched power amplifier stage. In one example, the nonuniform distributed power amplifier stage is electrically “upstream” from the reactively matched power amplifier stage. In one particular embodiment, power amplifier 10 includes a first stage 12, a second stage 14, and a third stage 16. The term electrically “upstream” refers to the placement of one component in power amplifier 10 relative to another component, wherein being electrically “upstream” would refer to a first component being located, or its processing occurring, prior to the second component. On a similar note, when a component is referred to being as electrically “downstream” from another component, the second component is located, or its processing would occur, after or subsequent to the first component.

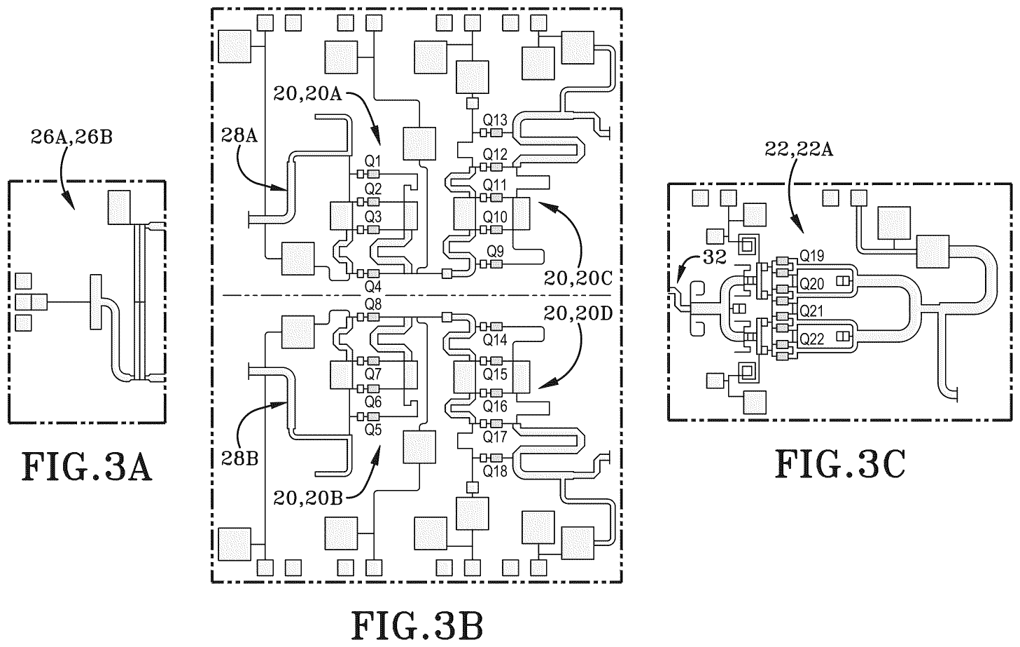

As depicted in FIG. 1, FIG. 2, and FIG. 3B, the first stage 12 comprises nonuniform distributed power amplifier circuitry 20. More particularly, a first nonuniform distributed power amplifier circuitry 20A is electrically parallel to a second nonuniform distributed power amplifier circuitry 20B. The first NDPA circuitry 20A is coupled to a drain voltage (Vd1) and a gate voltage (Vg1). The second NDPA circuitry 20B is coupled to a drain voltage (Vd1) and a gate voltage (Vg1). In one exemplary embodiment, the power amplifier 10 is symmetric about two equal halves that within which the signal processing occurs in parallel. As such, there may be a drain voltage (Vd1) and a gate voltage (Vg1) for the first half or upper half of the circuitry 20A and there may be a second drain voltage (Vd1) and a second gate voltage (Vg1) for the second or low half of the circuitry 20B.

The second stage 14 includes distributed power amplifier circuitry 20. More particularly, the second stage 14 includes a third NDPA circuitry 20C that is electrically parallel with a fourth NDPA circuitry 20D. The third NDPA circuitry 20C is coupled to a drain voltage (Vd2) and a gate voltage (Vg2). The fourth NDPA circuitry 20D is coupled to a drain voltage (Vd2) and a gate voltage (Vg2).

The first NPDA circuitry 20A is electrically in series with the third NDPA circuitry 20C. The second NDPA circuitry 20B is electrically in series with the fourth NDPA circuitry 20D.

As depicted in FIG. 1, FIG. 2, and FIG. 3C, the third stage 16 includes reactively matched power amplifier circuitry. More particularly, the third stage 16 includes a first reactively matched power amplifier circuitry 22A that is electrically in parallel with a second reactively matched power amplifier circuitry 22B. The first RMPA circuitry 22A is coupled to a drain voltage (Vd3) and a gate voltage (Vg3). The second RMPA circuitry 22B is coupled to a drain voltage (Vd3) and a gate voltage (Vg3). The first reactively matched power amplifier circuitry 22A is electrically in series with the third distributed power amplifier circuitry 20C and the second reactively matched power amplifier circuitry 22B is electrically in series with the fourth distributed power amplifier circuitry 20D.

As depicted in FIG. 1, FIG. 2, and FIG. 3A, to feed the three stages 12, 14, 16, the power amplifier 10 includes a radio frequency (RF) input 24. The input 24 is in electrical communication with a hybrid coupler 26A. In one embodiment, the hybrid coupler 26A is a Lange coupler, however other types of hybrid couplers may be utilized. From the hybrid coupler 26A, the RF signal is split into two parallel streams as indicated by lines 28A, 28B. The first line 28A carrying the signal from the hybrid coupler 26A feeds the first distributed power amplifier 20A, the third distributed power amplifier 20C and the first reactively matched power amplifier circuitry 22A that are all in series with each other. The second line 28B feeds the second distributed power amplifier circuitry 20B, the fourth distributed power amplifier circuitry 20D, and the second reactively matched power amplifier circuitry 22B that are in electrical series with each other. The output of the reactive matched power amplifier circuitry 22 in the third stage 16 are combined in a second hybrid coupler 26B, which may be a Lange coupler or other type of hybrid coupler. The output of the second hybrid coupler 26B is sent to a RF output 30.

In this exemplary embodiment of power amplifier 10, the first distributed power amplifier circuitry 20A includes, at least, four unit cells which may be four 2×75 micron field-effect transistors (FET). In FIG. 2, these four FET transistors are labeled as Q1, Q2, Q3, and Q4. The second distributed power amplifier circuitry 20B includes, at least, four unit cells which may be four 2×75 micron FET transistors. In FIG. 2, these four FET transistors are labeled as Q5, Q6, Q7, and Q8. Thus, there are, at least, eight total unit cells or eight total 2×75 micron FET transistors (Q1-Q8) in the first stage 12. However, it should be noted that other exemplary embodiments may have differing numbers of transistors in the first stage. Further, the use of FET transistors is not necessary as other transistors may be utilized, albeit FET transistors are preferable given the current state of transistor technology. Note, a “unit cell” is a fundamental unit in a layout of a semiconductor integrated circuit device.

The second stage 14 includes, at least, ten total FET transistors. Within the second stage 14 there are, at least, five unit cells which may be five 2×75 micron FET transistors in the third distributed power amplifier circuitry 20C. In FIG. 2, these five FET transistors are labeled as Q9, Q10, Q11, Q12, and Q13. There are, at least, five unit cells which may be five 2×75 micron FET transistors in the fourth distributed power amplifier circuitry 20D. In FIG. 2, these five unit cells or five FET transistors are labeled as Q14, Q15, Q16, Q17, and Q18. Thus, there are at least ten total unit cells or FET transistors (Q9-Q18) in the second stage 14.

There are, at least, eight total FET transistors in the third stage 16, wherein the first reactively matched power amplifier circuitry 22A includes, at least, four unit cells which may be four 4×75 micron FET transistors. In FIG. 2, these four FET transistors are labeled as Q9, Q19, Q20, Q21, and Q22. The second reactively matched power amplifier includes, at least, four unit cells which may be four 4×75 micron FET transistors. In FIG. 2, these five FET transistors are labeled as Q23, Q24, Q25, and Q26. In this particular embodiment, all twenty-six of the FET transistors (Q1-Q26) are approximately 0.18 microns long and 75 microns wide. The base layer forming the power amplifier 10 may have air cut vias through all of the substrates with the top side gold and silicon nitride removed. The backside gold maybe 2 microns thick.

In this exemplary embodiment of power amplifier 10, there are two distributive power amplifier stages 12,14 before the reactively matched power amplifier stage 16. The first stage 12 has a periphery value of 600 microns. The second stage 14 has a periphery value of 750 microns. The third stage 16 has a periphery value of 1200 microns. The ratio between each respective successive stages is less than 2:1 for example the ratio of the second stage 14 to the first stage is less than 2:1 (750 microns to 600 microns is less than a ratio of 2:1). Similarly, the ratio of the third stage 16 to the second stage 14 is less than 2:1. Stated otherwise, the value of 1200 microns to 750 microns is less than 2:1. Other embodiments may have differing numbers of distributed power amplifier stages and reactively matched power amplifier stages. The periphery is a parameter or way to describe numerically the amount of transistor that is in a stage. The ratio that defines the periphery is taken from stage to stage. The ratio increases from stage to stage. Typically, the most conservative ratio is 2:1. This means that the subsequent stage is twice the periphery of the current stage. However, because the distributed topology produces less power, a ratio that is less than 2:1 should be utilized for some of the embodiments detailed herein. However, it is entirely possible for the ratio to be greater than 2:1 if desirable for an application specific need.

Power amplifier 10 includes two stages that are distributed power amplifier circuitry and a subsequent stage that is reactively matched. There is at least one stage that is a distributed power amplifier stage 20 or has distributed power amplifier circuitry that is in electrical operative communication before a subsequent reactively matched power amplifier circuitry 22. There is an interface is between the last distributed power amplifier circuitry 20 and before the reactively matched power amplifier circuitry 22. At this interface, the impedance is matched between the last distributed power amplifier stage and the first reactive matched power amplifier stage so that power flows efficiently between the two. Matching the impedances ensures that power flows efficiently through the circuit. This ensures that the bandwidth is not as limited. Stated otherwise, impedances are matched between the objects or circuitry between the last distributed power amplifier circuitry and before the first reactively matched power amplifier circuitry to assist with power flow management.

“Periphery” is a measure of the size of a transistor. The periphery of a FET is measured in linear dimension of the gate width, such as in microns or millimeters. “Periphery ratio” is the ratio of the transistor sizes between stages.

In operation, power amplifier 10 provides a matched amplifier architecture to eliminate complex inter-stage impedance by maintaining the periphery ratio between each respective successive stages less than 2:1. The NDPA stages have nearly pure real input/output impedances to make the inter-stage matching a match between one real impedance (output impedance of the NDPA stage) and one complex impedance (input impedance of the RMPA stage) which improves bandwidth over matching between two complex impedances, which happens in a pure RMPA inter-stages. The distributed power amplifier circuitry 20 is designed using the nonuniform distributed power amplifier topology that increases the maximum output power by presenting an optimized output power load conductance to each of the transistor sections. The FET output capacitances of the distributed power amplifier circuitry 20 may be absorbed in an artificial transmission line. Tapering the drain line characteristic may better maintain an optimum load for all of the FET cells. Capacitors in the distributed power amplifier circuitry 20 may be placed in series with the gate of each FET in order to increase the cut-off frequency of the gate transmission line. These series capacitors are also tapered to ensure equal drive levels on the transistor gates. A Mesa or TaN resistor may be placed in parallel with each gate capacitor to provide a DC path for the gate bias. Alternatively, a NiCr resistor or other type of resistor could be utilized. The reactively matched power amplifier circuitry 22 may achieve high output powers by connecting multiple active cells in parallel. By doing so, the total gate width of the power amplifier is increased and thus higher currents can be obtained. The reactively matched power amplifier circuitry 22 should be configured to achieve broadband behavior of a matching network.

In power amplifier 10, a signal, such as an RF signal that is to be amplified, is connected to input 24. The signal is transmitted to the first hybrid coupler 26A. The first hybrid coupler 26A splits the signal and transmits the signal along parallel transmission lines 28A and 28B. The first hybrid coupler 26A applies a 90 degree phase shift to the signal between the branches or transmission lines 28A and 28B. Therefore, the signal traveling along transmission line 28A will have a 90 degree phase shift relative to the signal traveling along transmission line 28B. In one embodiment, the coupler 26A splits the signal equally along lines 28A and 28B. The first transmission line 28A transmits a portion of the signal to be amplified to the first distributed power amplifier circuitry 20A in the first stage 12. The second transmission line 28B transmits a portion of the signal to be amplified to the second distributed power amplifier circuitry 20B in the first stage 12. The signal is amplified in the first stage 12 by distributed power amplifier circuitry 20. Namely, the first portion of the signal is amplified by the four 2×75 micron FET transistors (Q1-Q4) in the first distributed power amplifier circuitry 20A. The second portion of the signal is amplified by the four 2×75 micron FET transistors (Q5-Q8) in the second distributed power amplifier circuitry 20B.

The first portion of the amplified signal exits the first distributed power amplifier circuitry 20A in the first stage 12 and is transmitted to the third distributed power amplifier circuitry 20C in the second stage 14. This signal is amplified by the, at least, five 2×75 micron FET transistors (Q9-Q13) in the third distributed power amplifier circuitry 20C. The second portion of the amplified signal exits the second distributed power amplifier circuitry 20B in the first stage 12 and is transmitted to the fourth distributed power amplifier circuitry 20D in the second stage 14. This signal is amplified by the, at least, five 2×75 micron FET transistors (Q14-Q18) in the fourth distributed power amplifier circuitry 20D.

The portion of the signal exiting the third distributed power amplifier circuitry 20C transitions through the interface 32 between the second stage 14 and the third stage 16. The impedance of the signal exiting the third distributed power amplifier circuitry 20C is matched to the reactively matched power amplifier circuitry 22A in the third stage 16 so that power flows efficiently between them. The portion of the signal exiting the fourth distributed power amplifier circuitry 20D transitions through the interface 32 between the second stage 14 and the third stage 16. The impedance of the signal exiting the fourth distributed power amplifier circuitry 20D is matched to the reactively matched power amplifier circuitry 22B stage so that power flows efficiently between them. The interface 32 may be an intermediate impedance interface.

In one exemplary embodiment, matching the impedance of the signal at the interface between the last distributed power amplifier circuitry 20 and before the reactively matched power amplifier circuitry 22 is accomplished through a wideband impedance matching practice, and comprising in this exemplary embodiment a series of transmission lines, shunt transmission line stubs, shunt shorted MIM capacitors, and series MIM capacitors.

The portion of the signal exiting the third distributed power amplifier circuitry 20C transitions through the interface 32 between the second stage 14 and the third stage 16 is then amplified by the first reactively matched power amplifier circuitry 22A via, at least, four 4×75 micron FET transistors (Q19-Q22). The portion of the signal exiting the fourth distributed power amplifier circuitry 20D transitions through the interface between the second stage 14 and the third stage 16 is then amplified by the second reactively matched power amplifier circuitry 22B via, at least, four 4×75 micron FET transistors (Q23-Q26). The second hybrid coupler then receives the amplified signal from the first reactively matched power amplifier circuitry 22A and the second reactively matched power amplifier circuitry 22B. Second hybrid coupler 26B combines the two signals and transmits the amplified signal to the output 30.

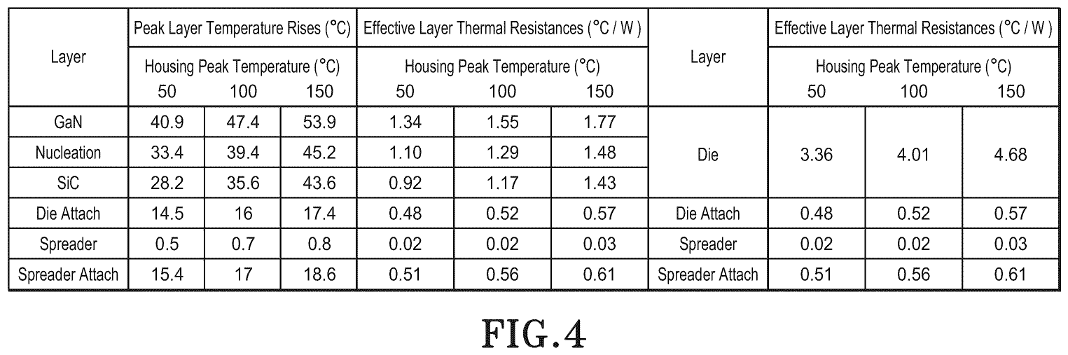

Because the efficiency of the power amplifier of the present disclosure is improved, the thermal performance is also improved. FIG. 4 is a table that depicts the stackup temperature rises and effective thermal resistances. The values in the table shown in FIG. 4 are based expressly on 36.5 GHz operation of the power amplifier, which according to this embodiment, results in maximum peak channel temperatures. Particularly, the total die heat dissipation is 30.49 W (Q_{die} (W)=30.49). The effective thermal resistance values may vary significantly, even though the stackups are identical and the die features are similar. This is largely due to the selection of total die heat dissipation to calculate the effective thermal resistance values. The layer temperature rises are primarily due to FET transistor heat dissipations in the channel at the top of the die and the local effect diminishes as heat flows down through the stackup, until the layer temperature is more strongly due to the total die heat dissipation. The remaining amount of variation is primarily due to differences in die layout and heat distribution, with temperature-dependent effects being secondary. The layer temperature rises and effective thermal resistances shown in the table of FIG. 4 are not only limited to the range of housing peak temperatures but also on the total die heat dissipation and heat distribution implied by the referenced operating frequency.

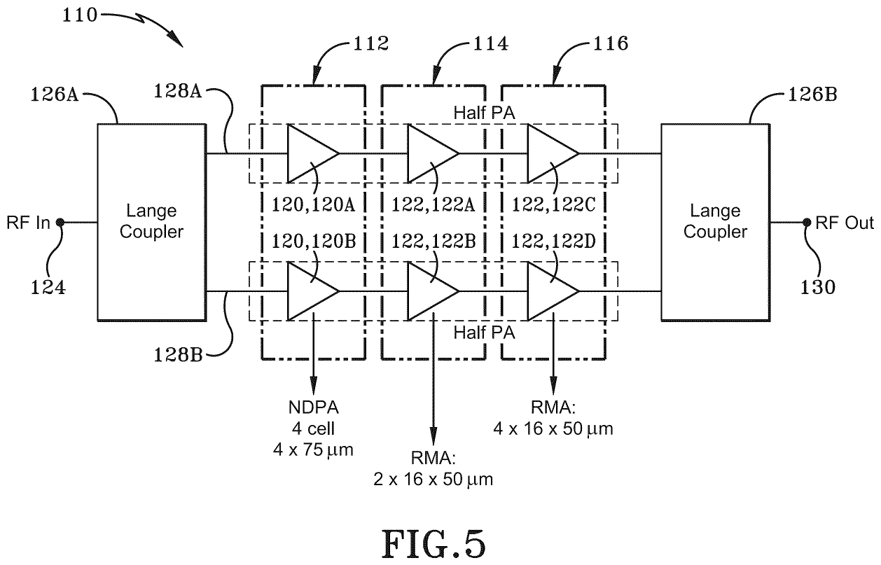

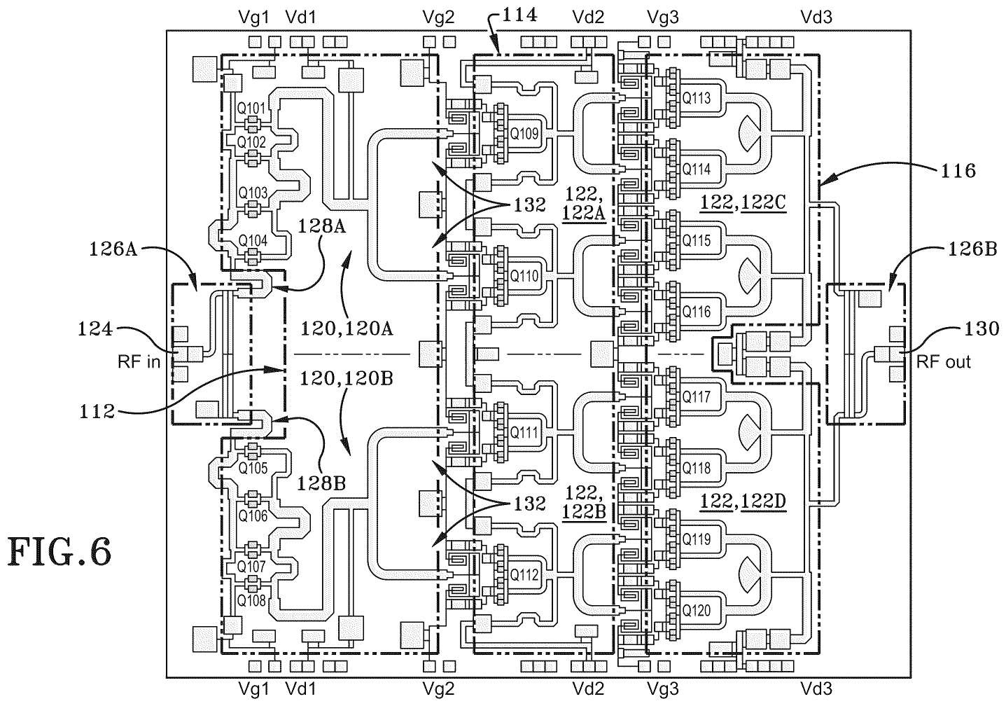

FIG. 5 schematically depicts the configuration of a power amplifier according to a second embodiment of the present disclosure generally at 110. FIG. 6 depicts an exemplary topology or configuration of the power amplifier 110.

Power amplifier 110 combines a nonuniform distributed power amplifier and a reactively matched power amplifier topology into a single power amplifier 110. Power amplifier 110 includes at least two stages, wherein at least one of the stages is a nonuniform distributed power amplifier stage and at least one of the other stages is a reactively matched power amplifier stage. More particularly, power amplifier 10 includes a first stage 112, a second stage 114, and a third stage 116.

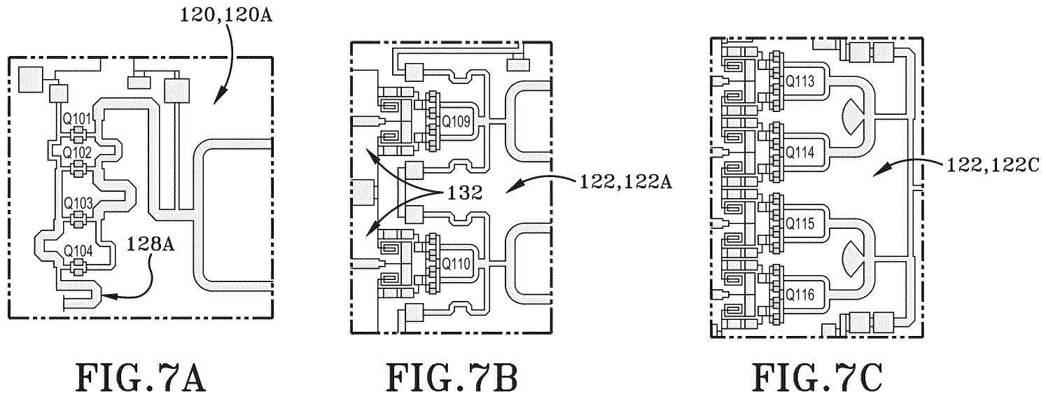

As depicted in FIG. 5, FIG. 6, and FIG. 7A, the first stage 112 comprises nonuniform distributed power amplifier circuitry 120. More particularly, a first distributed power amplifier circuitry 120A is electrically parallel to a second distributed power amplifier circuitry 120B.

As depicted in FIG. 5, FIG. 6, and FIG. 7B, the second stage 114 includes reactively matched power amplifier circuitry 122. More particularly, the second stage 114 includes a first reactively matched power amplifier circuitry 122A that is electrically parallel with a second reactively matched power amplifier circuitry 122B. The first reactively matched power amplifier circuitry 122A is in series with the first nonuniform distributed power amplifier circuitry 120A. The second reactively matched power amplifier circuitry 122B is in electrical series with the second nonuniform distributed power amplifier circuitry 120B.

As depicted in FIG. 5, FIG. 6, and FIG. 7C, the third stage 16 includes reactively matched power amplifier circuitry 122. More particularly, the third stage 16 includes a third reactively matched power amplifier circuitry 122C that is electrically in parallel with a fourth reactively matched power amplifier circuitry 122D. The third reactively matched power amplifier circuitry 122C is electrically in series with the first reactively matched power amplifier circuitry 122A. The fourth reactively matched power amplifier circuitry 122D is electrically in series with the second reactively matched power amplifier circuitry 122B.

As depicted in FIG. 5 and FIG. 6, to feed the three stages 112, 114, 116, the power amplifier 110 includes a radio frequency (RF) input 124. The input 124 is in electrical communication with a hybrid coupler 126. In one embodiment, the hybrid coupler 126A is a Lange coupler, however other types of hybrid couplers may be utilized. From the hybrid coupler 126A, the RF signal is split into two parallel streams as indicated by lines 128A, 128B. The first line 128A carrying the signal from the hybrid coupler 126A feeds the first nonuniform distributed power amplifier 120A, the first reactively matched power amplifier circuitry 122A and the third reactively matched power amplifier circuitry 122C that are all in series with each other. The second line 128B feeds the second nonuniform distributed power amplifier circuitry 120B, the second reactively matched power amplifier circuitry 122B, and the fourth reactively matched power amplifier circuitry 122D that are in electrical series with each other. The output of the reactive matched power amplifier circuitry 122 in the third stage 116 are combined in a second hybrid coupler 126B, which may be a Lange coupler or other type of hybrid coupler. The output of the second hybrid coupler 126B is sent to a RF output 130.

In this exemplary embodiment of power amplifier 110, the first nonuniform distributed power amplifier circuitry 120A includes, at least, four unit cells which may be four 4×75 micron (FET) transistors as shown by transistors Q101, Q102, Q103, and Q104. The second distributed power amplifier circuitry 120B includes, at least, four unit cells which may be four 4×75 micron FET transistors as shown by transistors Q105, Q106, Q107, and Q108. Thus, there are, at least, eight total FET transistors (4×75 micron) in the first stage 112 (as shown at Q101-Q108). The second stage 114 includes, at least, four unit cells which may be four total FET transistors. Within the second stage 114 there are, at least, two 16×50 micron FET transistors in the first reactively matched power amplifier circuitry 122A as shown by Q109 and Q110. There are, at least, two 16×50 micron FET transistors in the second reactively matched power amplifier circuitry 122B as shown by Q111 and Q112. There are, at least, eight total unit cells which may be eight FET transistors in the third stage 116, wherein the third reactively matched power amplifier circuitry 122C includes, at least, four unit cells which may be four 16×50 micron FET transistors, as shown by transistors Q113, Q114, Q115, and Q116. The fourth reactively matched power amplifier circuitry 122D includes, at least, four unit cells which may be four 16×50 micron FET transistors as shown by transistors Q117, Q118, Q119, and Q120. In this particular embodiment, there would be at least twenty total FET transistors (i.e., transistors Q101-Q120). The base layer forming the power amplifier 110 may have air cut vias through all of the substrates with the top side gold and silicon nitride removed. The backside gold may be 2 microns thick.

In this exemplary embodiment of power amplifier 110, there is one nonuniform distributive power amplifier stage 112 before the two reactively matched power amplifier stages 114, 116. This embodiment has a periphery drive ratio of 1.5:2:4 for the first stage 112: second stage 114: third stage 116. Thus, if the first stage 112 has a periphery value of 450 microns, the second stage 114 has a periphery value of 600 microns, and the third stage 116 has a periphery value of 1200 microns. The ratio between each respective success stage is less than or equal to 2:1 for example the ratio of the second stage 114 to the first stage 112 is less than 2:1 (600 microns to 450 microns is less than then a ratio of 2:1). Similarly, the ratio of the third stage 116 to the second stage 114 is less or equal to 2:1. Stated otherwise, the value of 1200 microns to 600 microns is less than or equal to 2:1. Other embodiments may have differing numbers of distributed power amplifier stages and reactively match power amplifier stages.

Power amplifier 110 includes one stage that is a nonuniform distributed power amplifier and two subsequent stages that are reactively matched stages. This design approach is different from the previous embodiments (i.e., power amplifier 10) which utilized two distributed stages and a single subsequent reactively matched stage. However, either embodiment (i.e., power amplifier 10 or power amplifier 110) there is at least one stage that is a nonuniform distributed power amplifier stage or has nonuniform distributed power amplifier circuitry that is in electrical operative communication before a subsequent reactively matched power amplifier circuitry (i.e., the nonuniform distributed power amplifier circuitry is electrically “upstream” from the reactively matched power amplifier circuitry). In each embodiment, there is an interface 32 or 132 between the last distributed power amplifier circuitry 20 or 120 and before the first reactively matched power amplifier circuitry 22 or 122. At this interface 32 or 132, the impedance is matched between the last distributed power amplifier stage and the first reactively matched power amplifier stage so that power flows efficiently between the two. Matching the impedances ensures that power flows efficiently through the circuit. This ensures that the bandwidth is not as limited. Stated otherwise, impedances are matched between the objects or circuitry between the last distributed power amplifier circuitry and before the first reactively matched power amplifier circuitry to assist with power flow management.

In operation, power amplifier 110 provides a matched amplifier architecture to eliminate complex inter-stage impedance by maintaining the periphery ratio between each respective successive stages is less than or equal to 2:1. The distributed power amplifier circuitry 120 is designed using the nonuniform distributed power amplifier topology that increases the maximum output power by presenting an optimized output power load conductance to each of the transistor sections. The FET output capacitances of the distributed power amplifier circuitry 120 may be absorbed in an artificial transmission line. Tapering the drain line characteristic may better maintain an optimum load for all of the FET cells. Capacitors in the distributed power amplifier circuitry 120 may be placed in series with the gate of each FET in order to increase the cut-off frequency of the gate transmission line. These series capacitors are also tapered to ensure equal drive levels on the transistor gates. A NiCr resistor may be placed in parallel with each gate capacitor to provide a DC path for the gate bias. The reactively matched power amplifier circuitry 122 may achieve high output powers by connecting multiple active cells in parallel. By doing so, the total gate width of the power amplifier is increased and thus higher currents can be obtained. The reactively matched power amplifier circuitry 122 should be configured to achieve broadband behavior of a matching network.

In power amplifier 110, a signal, such as an RF signal that is to be amplified, is connected to input 124. The signal is transmitted to the first hybrid coupler 126A. The first hybrid coupler 126A splits the signal and transmits the signal equally along parallel transmission lines 128A and 28B. First transmission line 128A transmits a portion of the signal to be amplified to the first distributed power amplifier circuitry 120A in the first stage 12. Second transmission line 128B transmits a portion of the signal to be amplified to the second distributed power amplifier circuitry 20B in the first stage 112. The signal is amplified in the first stage 112 by distributed power amplifier circuitry 120. Namely, the first portion of the signal is amplified by the four 4×75 micron FET transistors Q101-Q104 in the first distributed power amplifier circuitry 120A. The second portion of the signal is amplified by the four 4×75 micron FET transistors Q105-Q108 in the second distributed power amplifier circuitry 120B.

The portion of the signal exiting the first distributed power amplifier circuitry 120A transitions through the interface 132 between the first stage 112 and the second stage 114. The impedance of the signal exiting the second distributed power amplifier circuitry 120A is matched to the reactively matched power amplifier circuitry 122A stage so that power flows efficiently between them. The portion of the signal exiting the second distributed power amplifier circuitry 120B transitions through the interface 132 between the first stage 112 and the second stage 114. The impedance of the signal exiting the second distributed power amplifier circuitry 120B is matched to the reactively matched power amplifier circuitry 122B stage so that power flows efficiently between them. The interface 132 may be an intermediate impedance interface.

In one exemplary embodiment, matching the impedance of the signal at the interface 132 between the last distributed power amplifier circuitry 20 (i.e., first stage 112) and before the reactively matched power amplifier circuitry 22 (i.e., second stage 114) is accomplished through a wideband impedance matching practices, and comprising in this exemplary embodiment a series of transmission lines, shunt shorted MIM capacitors, and series MIM capacitors.

The first portion of the amplified signal exits the first distributed power amplifier circuitry 120A in the first stage 112 and is transmitted to the first reactively matched power amplifier circuitry 122A in the second stage 114. This signal is amplified by the, at least, two 16×50 micron FET transistors Q109 and Q110 in the first reactively matched power amplifier circuitry 122A. The second portion of the amplified signal exits the second distributed power amplifier circuitry 120B in the first stage 12 and is transmitted to the second reactively matched power amplifier circuitry 122B in the second stage 14. This signal is amplified by the, at least, two 16×50 micron FET transistors Q111 and Q112 in the second reactively matched power amplifier circuitry 122B.

The portion of the signal exiting the first reactively matched power amplifier circuitry 122A is then amplified by the third reactively matched power amplifier circuitry 122C via, at least, four 16×50 micron FET transistors Q113-Q116. The portion of the signal exiting the second reactively matched power amplifier circuitry 122B is then amplified by the fourth reactively matched power amplifier circuitry 122D via, at least, four 16×50 micron FET transistors Q117-Q120. The second hybrid coupler then receives the amplified signal from the third reactively matched power amplifier circuitry 122C and the fourth reactively matched power amplifier circuitry 122D. Second hybrid coupler 126B combines the two signals and transmits the amplified signal to the output 130.

Table 1 (below) indicates the parameters of the power amplifier 10 or 110 topology of the present disclosure and the specifications achieved for each respective parameter.

TABLE 1

| Parameter | Specification | |
|---|---|---|
| DC Input Power | 80 W max. @P7 dB | |
| Output Power | 39.5 dBm to 41.36 dBm @P7 dB | |
| Bandwidth | 28-40 | GHz |
| Small-Signal Gain | 20.55 +/− 2.35 | dB |
| Gain Flatness | +/−2.35 | dB |
| In/Out Return Loss (ON/OFF) | 23 | dB |
| Drain Voltage | 20 | V |
| 2^{nd}/3^{rd} Harmonics | −45 | dBc |

| | |
|---|---|
| Stability | Stable for 2.0:1 source/load |
| | VSWRs, all phases |
| Power Dissipation | Below 7 W/mm |
| Temperature | −54° C. to +125° C. |
| Size | 7 mm × 6 mm |

With respect to power amplifier circuits or circuitry there is a tradeoff between bandwidth and DC (direct current) power. DC power is the input to the power amplifier circuitry to obtain the output power. What governs a relationship of input power to output power is the efficiency of the power amplifier. Ordinarily circuit designers are limited on input power and desire the most output power possible. Therefore, circuit designers want the highest efficiency possible. How much output power can be obtained per the efficiency is governed by the bandwidth. Typically, a reactively matched power amplifier can be performed at about up to 20% bandwidth. Beyond that 20% bandwidth, a distributed power amplifier can obtain higher bandwidths or higher bandwidth percentages, typically well over 100%, however, the reactively matched power amplifier that is limited in bandwidth has a higher efficiency compared to an architecture like a distributed power amplifier that has a broad bandwidth but a low efficiency or limited efficiency. Recall, the efficiency governs the amount of output power for a given amount of DC input power. The different embodiments of the combination power amplifiers 10 or 110 described herein take advantage of both of these features. The embodiments of the power amplifier(s) 10 or 100 of the present disclosure utilize a combination of the two architectures to find a “middle ground” that has multiple stages. The earlier stages are distributed power amplifier topologies. The later stages largely govern the power performance and the efficiency performance, and those later stages are reactively matched. This combination allows the power amplifiers 10 or 110 of the present disclosure to achieve a performance that is between the other two architectures alone. Thus, the power amplifier 10 or 110 of the present disclosure can achieve broader bandwidth than a pure or sole reactively matched power amplifier but not as broad as a distributed power amplifier, but also obtain better efficiency than a pure or sole distributed amplifier, but not quite as high as a reactively matched power amplifier. This results in a solution that's a hybrid or combination between the two versions that were available. For example, for a 32-38 GHz power amplifier, the power amplifier 10 or 110 of the present disclosure can achieve efficiency ratios that are higher than previously available. More particularly, power amplifier 10 or 110 may have an operative bandwidth that ranges from 28-40 Ghz. There is a criteria called the Bode-Fano criteria that determines how well of a match and how broad the bandwidth can be depending on the impedances that are trying to be matched. Stated otherwise, the Bode-Fano criterion states that, for any passive, linear, and time-invariant matching network, there is a stringent tradeoff between the matching bandwidth and efficiency, implying severe constraints on various electromagnetic systems. Thus, having one stage that improves the bandwidth enables the power amplifier of the present disclosure to eliminate the bandwidth limiting factor.

As described herein, aspects of the present disclosure may include one or more electrical or other similar secondary components and/or systems therein. The present disclosure is therefore contemplated and will be understood to include any necessary operational components thereof. For example, electrical components will be understood to include any suitable and necessary wiring, fuses, or the like for normal operation thereof. It will be further understood that any connections between various components not explicitly described herein may be made through any suitable means including mechanical fasteners, or more permanent attachment means, such as welding or the like. Alternatively, where feasible and/or desirable, various components of the present disclosure may be integrally formed as a single unit.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone may be utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments. As such, one aspect or embodiment of the present disclosure may be a computer program product including least one non-transitory computer readable storage medium in operative communication with a processor, the storage medium having instructions stored thereon that, when executed by the processor, implement a method or process described herein, wherein the instructions comprise the steps to perform the method(s) or process(es) detailed herein.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software, and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A power amplifier comprising:
a first stage comprising a distributed power amplifier circuitry;
a second stage that is electrically operative after the first stage, the second stage comprising a reactively matched power amplifier circuitry;
an intermediate impedance interface between the first stage and the second stage; and
a periphery ratio of the second stage to the first stage that is less than or equal to 2:1.

2. The power amplifier of claim 1, wherein the first stage comprises at least two unit cells in the distributed power amplifier circuitry.

3. The power amplifier of claim 1, wherein the second stage comprises at least two unit cells in the reactively matched power amplifier circuitry.

4. The power amplifier of claim 1, further comprising:
a third stage that is electrically operative after the second stage, the third stage comprising another reactively matched power amplifier circuitry.

5. The power amplifier of claim 4, wherein the periphery ratio of the first stage to the second stage to the third stage increases from the first stage to the second stage to the third stage.

6. The power amplifier of claim 5, wherein the periphery ratio of the first stage to the second stage to the third stage is 1.5:2:4.

7. The power amplifier of claim 4, wherein the third stage comprises at least two unit cells in the another reactively matched power amplifier circuitry.

8. The power amplifier of claim 1, further comprising:
an operative bandwidth of the power amplifier that ranges from 28-40 Ghz.

9. The power amplifier of claim 1, further comprising:
a first hybrid coupler coupled to an input of the power amplifier, wherein the input is electrically operative before the first stage; and
a second hybrid coupler coupled to an output of the power amplifier, wherein the output is electrically operative after the second stage.

10. The power amplifier of claim 1, wherein the intermediate impedance interface is a non-50 Ohm intermediate impedance.

11. A method for a power amplifier, the method comprising:
transmitting a signal to be amplified to a first stage of a power amplifier, wherein the first stage includes distributed power amplifier circuitry;
amplifying the signal in the first stage;
transmitting the signal to a second stage through an intermediate impedance interface between the first stage and the second stage, wherein the second stage includes reactively matched power amplifier circuitry;
amplifying the signal in the second stage; and
maintaining a periphery ratio of the second stage to the first stage to be less than or equal to 2:1.

12. The method of claim 11, further comprising:
transmitting the signal to a third stage that is electrically operative after the second stage, wherein the third stage includes reactively matched power amplifier circuitry; and
amplifying the signal in the third stage.

13. The method of claim 12, wherein the periphery ratio of the first stage to the second stage to the third stage increases from the first stage to the second stage to the third stage.

14. The method of claim 13, wherein the periphery ratio of the first stage to the second stage to the third stage is 1.5:2:4.

15. The method of claim 11, further comprising:
maintaining the intermediate impedance interface at a non-50 Ohm intermediate impedance.

16. The method of claim 11, further comprising:
matching at least one real impedance from an output impedance of the first stage with at least one complex impedance of an input impedance of the second stage that is adapted to improve bandwidth compared to matching two complex impedances.

17. A power amplifier comprising:
a distributed power amplifier stage;
a reactively matched power amplifier stage that is electrically coupled to the distributed power amplifier stage; and
an intermediate impedance interface between the distributed power amplifier stage and the reactively matched power amplifier stage;
wherein there is a periphery ratio that is less than or equal to 2:1 between the distributed power amplifier stage and the reactively matched power amplifier stage.

18. The power amplifier of claim 17, wherein the intermediate impedance interface is a non-50 Ohm intermediate impedance.
